(19) United States
(12) Patent Application Publication
(10) Pub. No.: US 2023/0217635 A1
(43) Pub. Date: Jul. 6, 2023

(54) CONDUCTIVE FILM, PARTICULATE MATTER, SLURRY, AND METHOD FOR PRODUCING CONDUCTIVE FILM

(71) Applicant: Murata Manufacturing Co., Ltd., Nagaokakyo-shi (JP)

(72) Inventor: Yoshito SODA, Nagaokakyo-shi (JP)

(21) Appl. No.: 18/158,600

(22) Filed: Jan. 24, 2023

Related U.S. Application Data
(63) Continuation of application No. PCT/JP2021/029151, filed on Aug. 5, 2021.

(30) Foreign Application Priority Data
Aug. 13, 2020 (JP) 2020-136819

(51) Int. Cl. H05K 9/00; H01B 5/14; H01B 1/22

(52) U.S. Cl. CPC H05K 9/0088; H01B 1/22; H01B 5/14

(57) ABSTRACT

A conductive film that includes particles of a layered material including one or plural layers, wherein the one or plural layers include a layer body represented by: MₘXₙ, wherein M is at least one metal of Group 3, 4, 5, 6, or 7, X is a carbon atom, a nitrogen atom, or a combination thereof, n is 1 to 4, and m is more than n and 5 or less, and a modifier or terminal T exists on a surface of the layer body, wherein T is at least one selected from the group consisting of a hydroxyl group, a fluorine atom, a chlorine atom, an oxygen atom, or a hydrogen atom, and wherein a χ-axis direction rocking curve half-value width for a peak of a (001) plane (1 is a natural number multiple of 2) obtained by X-ray diffraction measurement of the conductive film is 10.3° or less.

### CROSS REFERENCE TO RELATED APPLICATIONS

The present application is a continuation of International application No. PCT/JP2021/029151, filed Aug. 5, 2021, which claims priority to Japanese Patent Application No. 2020-136819, filed Aug. 13, 2020, the entire contents of each of which are incorporated herein by reference.

### FIELD OF THE INVENTION

The present invention relates to a conductive film, a particulate matter, a slurry, and a method for producing a conductive film using the slurry.

### BACKGROUND OF THE INVENTION

In recent years, MXene has been attracting attention as a new material having conductivity. MXene is a type of so-called two-dimensional material, and as will be described later, is a layered material in a form of one or plural layers. In general, MXene is in a form of particles (which can include powders, flakes, nanosheets, and the like) of such a layered material.

It is known that MXene particles can be formed into a film on a substrate by subjecting the particles to suction filtration or spray coating in a slurry state. It has been reported that a film (conductive film) containing MXene particles exhibits an electromagnetic shielding effect. More specifically, it is considered that a film of Ti₃C₂Tₓ (without filler), which is one of MXene, has an electrical conductivity of 4665 S/cm, and with such an electrical conductivity, an excellent electromagnetic shielding effect can be obtained (refer to FIG. 3B of Non-Patent Document 1.).

Non-Patent Document 1: Faisal Shahzad, et al., “Electromagnetic interference shielding with 2D transition metal carbides (MXenes)”, Science, 09 Sep. 2016, Vol. 353, Issue 6304, pp. 1137-1140

### SUMMARY OF THE INVENTION

However, the conductivity reported in Non-Patent Document 1 is only 4665 S/cm at the maximum. In order to obtain a sufficient effect as an electromagnetic shield, it is necessary to achieve higher conductivity.

The present invention is directed to a conductive film which contains MXene and achieves higher conductivity. The present invention is further directed to a particulate matter capable of providing such a conductive film, a slurry containing the particulate matter, and a method for producing a conductive film using the slurry.

According to a first gist of the present invention, provided is a conductive film including particles of a layered material including one or plural layers,
wherein the one or plural layers include a layer body represented by:
   MₘXₙ
   wherein M is at least one metal of Group 3, 4, 5, 6, or 7,
   X is a carbon atom, a nitrogen atom, or a combination thereof,
   n is 1 to 4, and
   m is more than n and 5 or less,
and a modifier or terminal T exists on a surface of the layer body, wherein the modifier or terminal T is at least one selected from the group consisting of a hydroxyl group, a fluorine atom, a chlorine atom, an oxygen atom, or a hydrogen atom, and
wherein a χ-axis direction rocking curve half-value width for a peak of a (001) plane (1 is a natural number multiple of 2) obtained by X-ray diffraction measurement of the conductive film is 10.3° or less.

In one aspect of the first gist of the present invention, the χ-axis direction rocking curve half-value width may be 8.8° or less.

In one aspect of the first gist of the present invention, the conductive film may have a conductivity of 12,000 S/cm or more.

In one aspect of the first gist of the present invention, the conductive film may have a density of 3.00 g/cm³ or more.

In one aspect of the first gist of the present invention, the conductive film may have an arithmetic average roughness of 120 nm or less.

In one aspect of the first gist of the present invention, the conductive film can be used as an electromagnetic shield.

According to a second gist of the present invention, provided is a particulate matter including: particles of a layered material including one or plural layers, wherein the one or plural layers include a layer body represented by:
MₘXₙ
wherein M is at least one metal of Group 3, 4, 5, 6, or 7,
X is a carbon atom, a nitrogen atom, or a combination thereof,
n is 1 to 4, and
m is more than n and 5 or less,
and a modifier or terminal T exists on a surface of the layer body, wherein the modifier or terminal T is at least one selected from the group consisting of a hydroxyl group, a fluorine atom, a chlorine atom, an oxygen atom, or a hydrogen atom; and
particles containing A,
wherein a ratio of the A to the M is 0.30 mol% or less, and
wherein the A is at least one element of Group 12, 13, 14, 15, or 16.

According to a third gist of the present invention, provided is a particulate matter including particles of a layered material including one or plural layers, wherein the one or plural layers include a layer body represented by:
MₘXₙ
wherein M is at least one metal of Group 3, 4, 5, 6, or 7,
X is a carbon atom, a nitrogen atom, or a combination thereof,
n is 1 to 4, and
m is more than n and 5 or less,
and a modifier or terminal T exists on a surface of the layer body, wherein the modifier or terminal T is at least one selected from the group consisting of a hydroxyl group, a fluorine atom, a chlorine atom, an oxygen atom, or a hydrogen atom, and
wherein a ratio of the particles of the layered material more than 20 nm in thickness in the particulate matter is less than 2%.

According to a fourth gist of the present invention, provided is a particulate matter including particles of a layered material including one or plural layers, wherein the one or plural layers include a layer body represented by:
MₘXₙ wherein
M is at least one metal of Group 3, 4, 5, 6, or 7,
X is a carbon atom, a nitrogen atom, or a combination thereof,
n is 1 to 4, and
m is more than n and 5 or less,
and a modifier or terminal T exists on a surface of the layer body, wherein the modifier or terminal T is at least one selected from the group consisting of a hydroxyl group, a fluorine atom, a chlorine atom, an oxygen atom, or a hydrogen atom, and
wherein a maximum thickness of the particles of the layered material contained in the particulate matter is 500 nm or less.

In one aspect of the fourth gist of the present invention, a ratio of particles more than 20 nm in thickness in the particulate matter may be less than 2%.

In one aspect of the third or fourth gist of the present invention, a ratio of A to the M is 0.30 mol% or less, and the A may be at least one element of Group 12, 13, 14, 15, or 16.

In any one of the second to fourth gists of the present invention, the M may be Ti, and the A may be Al.

According to a fifth gist of the present invention, provided is a slurry including the particulate matter according to any one of the second to fourth gist in a liquid medium.

According to a sixth gist of the present invention, provided is a method for producing a conductive film, the method including: (a) applying the slurry according to the fifth gist of the present invention onto a substrate to form a precursor of the conductive film including particles of the layered material; and (b) drying the precursor.

In one aspect of the sixth gist of the present invention, the application of the slurry in the (a) step may be performed by a spray, spin cast, or blade method.

In one aspect of the sixth gist of the present invention, the (a) and the (b) steps can be repeated twice or more in total.

The conductive film according to the first gist of the present invention can be produced by the method for producing a conductive film according to the sixth gist of the present invention.

According to the present invention, provided is a conductive film including particles of a predetermined layered material (also referred to as “MXene” in the present specification) and having a χ-axis direction rocking curve half-value width of 10.3° or less, thereby including MXene and being capable of achieving higher conductivity. Further, according to the present invention, there are also provided a particulate matter capable of providing such a conductive film, a slurry containing the particulate matter, and a method for producing the conductive film using the slurry.

### BRIEF DESCRIPTION OF THE DRAWINGS

FIGS. 1(a) and 1(b) are diagrams illustrating a conductive film in one embodiment of the present invention, in which FIG. 1(a) illustrates a schematic cross-sectional view of the conductive film on a substrate, and FIG. 1(b) illustrates a schematic perspective view of a layered material in the conductive film.

FIGS. 2(a) and 2(b) are schematic cross-sectional views illustrating MXene particles which are layered materials usable in one embodiment of the present invention, in which FIG. 2(a) illustrates single-layered MXene particles, and FIG. 2(b) illustrates multi-layered (exemplarily two-layered) MXene particles.

FIG. 3(a) to 3(d) are schematic cross-sectional views for explaining a method for producing a slurry in one embodiment of the present invention.

FIGS. 4(a) and 4(b) are schematic cross-sectional views for explaining a method for producing a conductive film in one embodiment of the present invention.

FIG. 5 is a graph plotting an equivalent circle diameter (µm) and the luminance of particles contained in the MXene slurry of Comparative Example 1.

FIG. 6 is a graph plotting the equivalent circle diameter (µm) and the luminance of particles contained in the MXene slurry of Example 1.

FIG. 7 is a graph plotting the equivalent circle diameter (µm) and the luminance of particles contained in the MXene slurry of Example 2.

FIG. 8(a) is a graph showing a distribution ratio of particle luminance contained in MXene slurries of Comparative Example 1 and Examples 1 and 2, and FIG. 8(b) is a graph showing a part of FIG. 8(a) in an enlarged manner.

FIG. 9 illustrates a cross-sectional SEM photograph of a substrate-attached conductive film (sample) of Comparative Example 2 obtained using the MXene slurry of Comparative Example 1.

FIG. 10 illustrates a cross-sectional SEM photograph of a substrate-attached conductive film (sample) of Example 3 obtained using the MXene slurry of Example 1.

FIG. 11 illustrates a cross-sectional SEM photograph of a substrate-attached conductive film (sample) of Example 4 obtained using the MXene slurry of Example 2.

FIG. 12 is a diagram illustrating a conductive film produced by a conventional producing method, and illustrates a schematic cross-sectional view of a conductive film on a substrate.

### DETAILED DESCRIPTION OF THE INVENTION

Hereinafter, a conductive film, a particulate matter, a slurry containing the particulate matter, and a method for producing a conductive film using the slurry in one embodiment of the present invention will be described in detail, but the present invention is not limited to such an embodiment.

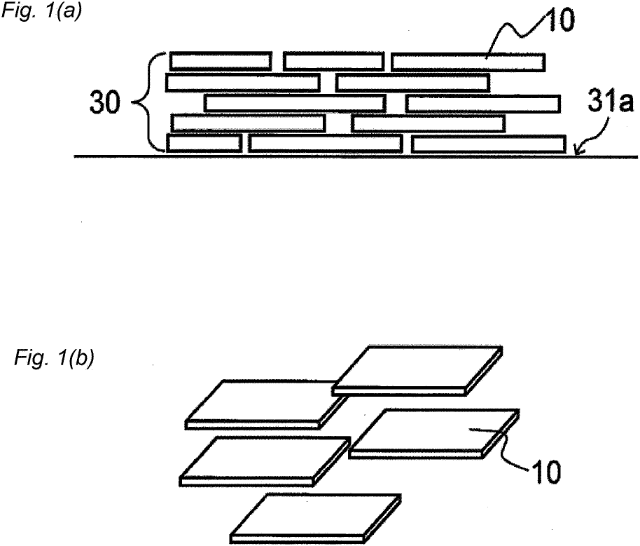

Referring to FIG. 1(a), a conductive film 30 of the present embodiment includes particles 10 of a predetermined layered material, and has a χ-axis direction rocking curve half-value width of 10.3° or less with respect to a peak of a (001) plane (1 is a natural number multiple of 2) obtained by X-ray diffraction measurement of the conductive film 30. Hereinafter, the conductive film 30 of the present embodiment will be described through the producing method.

The predetermined layered material that can be used in this embodiment is MXene and is defined as:
a layered material (this can be understood as a layered compound including one or plural layers, the one or plural layers including a layer body represented by:
MₘXₙ
wherein M is at least one metal of Group 3, 4, 5, 6, or 7 and may contain at least one selected from the group consisting of so-called early transition metals such as Sc, Ti, Zr, Hf, V, Nb, Ta, Cr, Mo, or Mn,
X is a carbon atom, a nitrogen atom, or a combination thereof,
n is 1 to 4,
m is more than n and 5 or less, and
a modifier or terminal T (T is at least one selected from the group consisting of a hydroxyl group, a fluorine atom, a chlorine atom, an oxygen atom, or a hydrogen atom) is present on the surface (more specifically, at least one of the two opposing surfaces of the layer body) of the layer body. The layer body may have a crystal lattice in which each X is located in an octahedral array of M. The layered compound is also represented as “MₘXₙTₛ”, where s is any number and traditionally x is sometimes used instead of s. Typically, n can be 1, 2, 3, or 4, but is not limited thereto.

In the above formula of MXene, M is preferably at least one selected from the group consisting of Ti, Zr, Hf, V, Nb, Ta, Cr, Mo, or Mn, and more preferably at least one selected from the group consisting of Ti, V, Cr, or Mo.

Such MXene can be synthesized by selectively etching (removing and optionally layer-separating) A atoms (and optionally parts of M atoms) from a MAX phase. The MAX phase is represented by the following formula:
MₘAXₙ
(wherein M, X, n, and m are as described above, and A is at least one element of Group 12, 13, 14, 15, or 16, is usually a Group A element, typically Group IIIA and Group IVA, more specifically, may include at least one selected from the group consisting of Al, Ga, In, Tl, Si, Ge, Sn, Pb, P, As, S, or Cd, and is preferably Al), and has a crystal structure in which a layer formed of A atoms is located between two layers (each X may have a crystal lattice located within an octahedral array of M) represented by MₘXₙ. Typically, in the case of m = n + 1, the MAX phase has a repeating unit in which one layer of X atoms is disposed between the layers of M atoms of n + 1 layers (these layers are also collectively referred to as “MₘXₙ layer”), and a layer of A atoms (“A atom layer”) is disposed as a next layer of the (n + 1) th layer of M atoms; however, the present invention is not limited thereto. By selectively etching (removing and optionally layer-separating) the A atoms (and optionally a part of the M atoms) from the MAX phase, the A atom layer (and optionally a part of the M atoms) is removed, and a hydroxyl group, a fluorine atom, a chlorine atom, an oxygen atom, a hydrogen atom, and the like existing in an etching liquid (usually, but not limited to, an aqueous solution of a fluorine-containing acid is used) are modified on the exposed surface of the MₘXₙ layer, thereby terminating the surface. The etching can be carried out using an etching liquid containing F⁻, and a method using, for example, a mixed liquid of lithium fluoride and hydrochloric acid, a method using hydrofluoric acid, or the like may be used.

As will be described later, in order to obtain a conductive film having high orientation of MXene particles and a predetermined rocking curve half-value width, it is preferable to perform etching so as to reduce the number of A atoms remaining in the MXene particles. The smaller amount of remaining A atoms contributes to further increasing the purity of the single layer MXene and further increasing the in-plane dimension of the single-layer MXene particles in the particulate matter to be described later and the slurry containing the particulate matter.

In addition, in order to obtain a conductive film having high orientation of the MXene particles and a predetermined rocking curve half-value width, it is preferable to perform a treatment for causing layer separation (delamination, separating multilayer MXene into fewer layers of MXene, preferably single-layer MXene) of MXene after etching. In order to obtain two-dimensional MXene particles (particles of single-layer/few-layer MXene, preferably single-layer MXene particles) having a larger aspect ratio, it is more preferable that such a layer separation treatment causes less damage to the MXene particles. The layer separation treatment can be performed by any appropriate method, for example, ultrasonic treatment, handshake, automatic shaker, or the like. However, since shearing force in the ultrasonic treatment is too large and the MXene particles may be broken (may be broken into small pieces), it is preferable to apply the appropriate shearing force by the handshake, automatic shaker, or the like. When the number of A atoms remaining in the MXene particles is smaller, the influence of the bonding force of the A atoms is smaller, so that the MXene particles can be effectively separated into layers with smaller shearing force.

MXenes whose above formula MₘXₙ is expressed as below are known:
Sc₂C, Ti₂C, Ti2N, Zr₂C, Zr₂N, Hf₂C, Hf₂N, V₂C, V₂N, Nb₂C, Ta₂C, Cr₂C, Cr₂N, Mo₂C, Mo_{1.3}C, Cr_{1.3}C, (Ti,V)₂C, (Ti,Nb)₂C, W₂C, W_{1.3}C, Mo₂N, Nb_{1.3}C, Mo_{1.3}Y_{0.6}C (in the above formula, “1.3” and “0.6” mean about 1.3 (= 4/3) and about 0.6 (= 2/3), respectively.),
Ti₃C₂, Ti₃N₂, Ti₃(CN), Zr₃C₂, (Ti,V)₃C₂, (Ti₂Nb)C₂, (Ti₂Ta)C₂, (Ti₂Mn)C₂, Hf₃C₂, (Hf₂V)C₂, (Hf₂Mn)C₂, (V₂Ti)C₂, (Cr₂Ti)C₂, (Cr₂V)C₂, (Cr₂Nb)C₂, (Cr₂Ta)C₂, (Mo₂Sc)C₂, (Mo₂Ti)C₂, (Mo₂Zr)C₂, (Mo₂Hf)C₂, (Mo₂V)C₂, (Mo₂Nb)C₂, (Mo₂Ta)C₂, (W₂Ti)C₂, (W₂Zr)C₂, (W₂Hf)C₂,
Ti₄N₃, V₄C₃, Nb₄C₃, Ta₄C₃, (Ti,Nb)₄C₃, (Nb,Zr)₄C₃, (Ti₂Nb₂)C₃, (Ti₂Ta₂)C₃, (V₂Ti₂)C₃, (V₂Nb₂)C₃, (V₂Ta₂)C₃, (Nb₂Ta₂)C₃, (Cr₂Ti₂)C₃, (Cr₂V₂)C₃, (Cr₂Nb₂)C₃, (Cr₂Ta₂)C₃, (Mo₂Ti₂)C₃, (Mo₂Zr₂)C₃, (Mo₂Hf₂)C₃, (Mo₂V₂)C₃, (Mo₂Nb₂)C₃, (Mo₂Ta₂)C₃, (W₂Ti₂)C₃, (W₂Zr₂)C₃, (W₂Hf₂)C₃

Typically in the above formula, M can be titanium or vanadium and X can be a carbon atom or a nitrogen atom. For example, the MAX phase is Ti₃AlC₂ and MXene is Ti₃C₂Tₛ (in other words, M is Ti, X is C, n is 2, and m is 3).

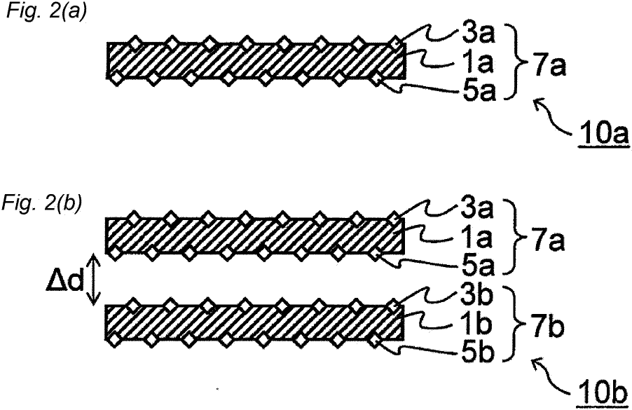

As schematically illustrated in FIGS. 2(a) and 2(b), the MXene particles 10 synthesized in this manner may be particles of a layered material (as examples of the MXene particles 10, the MXene particles 10a in one layer are illustrated in FIG. 2(a), and the MXene particles 10b in two layers are illustrated in FIG. 2(b), but the present invention is not limited to these examples) including one or plural MXene layers 7a and 7b. More specifically, the MXene layers 7a, 7b have layer bodies (MₘXₙ layers) 1a, 1b represented by MₘXₙ, and modifiers or terminals T 3a, 5a, 3b, 5b existing on the surfaces of the layer bodies 1a, 1b (more specifically, on at least one of both surfaces, facing each other, of each layer). Therefore, the MXene layers 7a, 7b are also represented by “MₘXₙTₛ,” wherein s is any number. The MXene particles 10 may be one in which such MXene layers are individually separated and exist in one layer (the single layer structure illustrated in FIG. 2(a), so-called single-layer MXene particles 10a), particles of a laminate in which a plurality of MXene layers are stacked apart from each other (the multilayer structure illustrated in FIG. 2(b), so-called multilayer MXene particles 10b), or a mixture thereof. The MXene particles 10 may be particles (which may also be referred to as powders or flakes) as an aggregate formed of the single-layer MXene particles 10a and/or the multilayer MXene particles 10b. In the case of multilayer MXene particles, two adjacent MXene layers (for example, 7a and 7b) do not necessarily have to be completely separated from each other, and may be partially in contact with each other. In the present embodiment, as will be described later, the MXene particles 10 preferably include as many single-layer MXene particles as possible (the content ratio of the single-layer MXene particles is high) as compared with the multilayer MXene particles.

Although the present embodiment is not limited, the thickness of each layer of MXene (which corresponds to the MXene layers 7a and 7b) may be, for example, 0.8 nm to 5 nm, particularly 0.8 nm to 3 nm (which may mainly vary depending on the number of M atom layers included in each layer). In a case where the MXene particles are particles of the laminates (multilayer MXene), for the individual laminates, the interlayer distance (alternatively, a void dimension indicated by Δd in FIG. 2(b)) is, for example, 0.8 nm to 10 nm, particularly 0.8 nm to 5 nm, and more particularly about 1 nm.

The thickness in the direction perpendicular to the layer of MXene particles (which may correspond to the “thickness” of the MXene particles as two-dimensional particles) is, for example, 0.8 nm to, for example, 20 nm, particularly 15 nm, more particularly 10 nm. The total number of layers of MXene particles may be 1 or 2 or more, and may be, for example, 1 to 10, and particularly 1 to 6. In a case where MXene particles are particles of the laminates (multilayer MXene), it is preferable that MXene particles have a small number of layers. The term “small number of layers” means, for example, that the number of stacked layers of MXene is 6 or less. The thickness, in the stacking direction, of the multilayer MXene particles having a small number of layers is preferably 15 nm or less, particularly 10 nm or less. In the present specification, the “multilayer MXene having a small number of layers” is also referred to as a “few-layer MXene”. In the present embodiment, most of the MXene particles are preferably single-layer MXene and/or few-layer MXene particles, and more preferably single-layer MXene particles. In other words, the average value of the thicknesses of the MXene particles is preferably 10 nm or less. The average value of the thickness is more preferably 7 nm or less, and still more preferably 5 nm or less. On the other hand, in consideration of the thickness of the single-layer MXene, the lower limit of the thickness of the MXene particles can be 0.8 nm. Therefore, the average value of the thickness of the MXene particles can be about 1 nm or more.

The dimension (which may correspond to the “in-plane dimension” of the MXene particles as two-dimensional particles) in a plane (two-dimensional sheet plane) parallel to the layer of MXene particles may be, for example, 0.1 µm or more, particularly 1 µm or more, and may be, for example, 200 µm or less, particularly 40 µm or less.

It should be noted that these dimensions described above may be determined as number average dimensions (for example, number average of at least 40) based on photographs of a scanning electron microscope (SEM), a transmission electron microscope (TEM), or an atomic force microscope (AFM), or as distances in the real space calculated from the positions on the reciprocal lattice space of the (002) plane measured by an X-ray diffraction (XRD) method.

The present inventor has examined factors affecting conductivity in order to realize conductivity higher than that in the related art (Non-Patent Document 1) in the conductive film 30 containing the MXene particles.

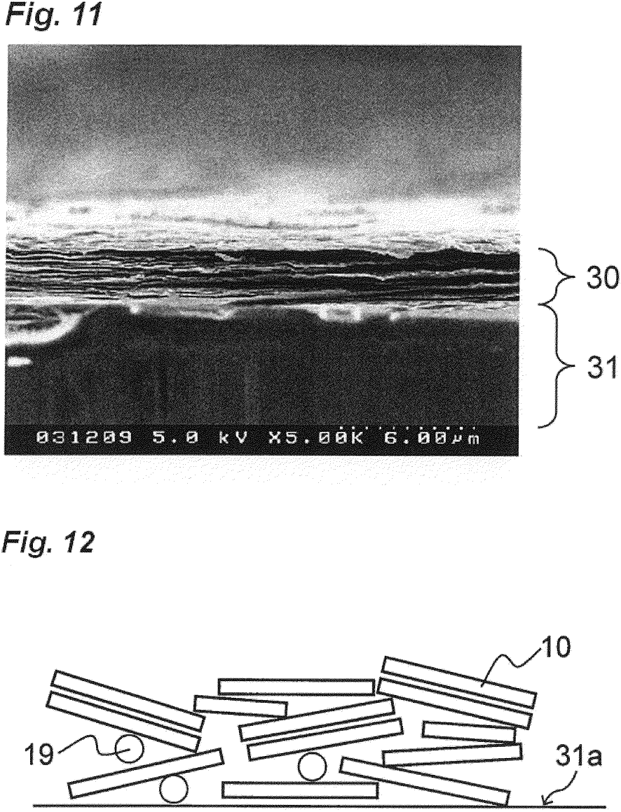

When the conductive film containing MXene particles is produced by a conventional method, as schematically illustrated in FIG. 12, the MXene particles (including multilayer MXene particles and single-layer MXene particles) 10 are present in a relatively disorderly stacked state on a substrate surface 31a (in other words, the main surface of the film), and impurities 19 other than the MXene particles 10 are present, so that the steric hindrance of the multilayer MXene particles and the impurities 19 inhibits the stacking of the single-layer MXene particles, and the orientation of the MXene particles is low as the entire conductive film. The conductive film containing MXene particles may have different physical properties depending on the orientation of the MXene particles in the film. As schematically illustrated in FIG. 12, when the orientation of the MXene particles 10 is low, the contact between the MXene particles 10 is poor (the conductive path is cut off), and the electron conductivity of the entire conductive film is poor, and hence it is considered that high conductivity cannot be obtained. Conversely, if the orientation of the MXene particles in the film is high, it is considered that a conductive film having higher conductivity can be obtained.

As a result of the study of the present inventor, it has been found that a particulate matter (which can be contained in a slurry and used in the present embodiment) as a raw material thereof is important in order to obtain a conductive film having high orientation of the MXene particles. More specifically, it is considered to be desirable to use a particulate matter that satisfies at least one of the following (1) and (2), particularly the following (1), preferably both of the following (1) and (2).
(1) The amount of impurities other than MXene is as small as possible.
(2) The number of the single-layer MXene particles is as many as possible (the content ratio of the single-layer MXene particles is high) as compared with the multilayer MXene particles.

In the conventional method for producing a conductive film, A atoms are selectively etched from a MAX phase, and then unnecessary components are substantially removed by centrifugation and removal of a supernatant (recovery/washing of precipitate) to prepare a slurry containing MXene particles in a liquid medium (aqueous medium). This is because the mixed liquid after etching contains MXene particles (single-layer MXene particles and multilayer MXene particles) and also contains unnecessary components such as impurities and an etching liquid. However, the particulate matter contained in the slurry thus obtained is not necessarily satisfactory in terms of the above (1) and/or (2).

As a result of further studies by the present inventor, it has been found that, as an index of the above (1) and/or (2), when a particulate matter (which can be contained in a slurry and used in the present embodiment) satisfies at least one of the following conditions, a conductive film having sufficiently high orientation and eventually high conductivity can be obtained.

It is more preferable as the ratio of A atoms to M atoms is smaller, and specifically, the ratio is 0.30 mol% or less.

The ratio of particles having a thickness of more than 20 nm in the particulate matter is preferably as small as possible, specifically, less than 2%.

It is preferable that the particulate matter does not contain particles having a too large thickness, and specifically, the maximum thickness of the particles contained in the particulate matter is 500 nm or less.

Based on the findings of the present inventor, the particulate matter of the present embodiment contains the MXene particles 10 described above and satisfies at least one of the following (I) to (III).
(I) In regard to M (at least one metal of Group 3, 4, 5, 6, of 7) and A (at least one element of Group 12, 13, 14, 15, or 16) in the above formula, the ratio of A to M is 0.30 mol% or less.
(II) The ratio of particles having a thickness of more than 20 nm in the particulate matter is less than 2%, preferably less than 1% (in other words, the ratio of particles having a thickness of 20 nm or less in the particulate matter is 98% or more, preferably 99% or more.).
(III) The maximum thickness of the particles contained in the particulate matter is 500 nm or less, preferably 250 nm or less, more preferably 100 nm or less, and still more preferably 50 nm or less (in other words, the particulate matter does not contain particles having a thickness more than 500 nm, preferably does not contain particles having a thickness more than 250 nm, more preferably does not contain particles having a thickness more than 100 nm, and even more preferably does not contain particles having a thickness more than 50 nm.).

In the above (I), typically, M may be Ti, and A may be Al.

From one point of view, it is considered as follows. In the above (1), unreacted MAX particles and crystals of by-products derived from etched A atoms (for example, crystals of AlF₃) constitute impurities. In the above (2), A atoms are likely to remain between the layers of the multilayer MXene particles, whereas if the number of single-layer MXene particles is large, the etched A atoms are likely to be released in the liquid medium and removed as unnecessary components. Therefore, satisfying the above (I) can indicate that the content of impurities is small and the content ratio of the single-layer MXene particles is high, and can satisfy the above (1) and (2). Furthermore, it is considered as follows. If the A atoms remain between the layers of the MXene particles after etching, the layer separation of the MXene particles can be inhibited by the bonding force of the A atoms, and if shearing force larger than the bonding force of the A atoms is applied to promote the layer separation, the MXene particles are fragmented, and the in-plane dimension of the MXene particles becomes small. When the A atom is small, the layer separation of the MXene particles can be effectively promoted with smaller shearing force, so that MXene particles (preferably single-layer MXene particles) having a larger in-plane dimension can be obtained. Therefore, satisfying the above (I) can indicate that the in-plane dimension of the MXene particles (particularly, the single-layer MXene particles) is relatively large.

Regarding the (I), the contents of the M and the A in the particulate matter (or slurry to be described later) can be measured by element (atom) analysis such as inductively coupled plasma atomic emission spectrometry (ICP-AES) or X-ray fluorescence analysis (XRF), and the ratio of A to M can be calculated from these measured values.

From another point of view, it is considered as follows. In the above (1), impurities other than MXene (for example, the above-described MAX particles) may have a dimension (thickness and/or particle size) larger than 20 nm. In the above (2), the thickness of the multilayer MXene particles is larger than the thickness of the single-layer MXene particles and is more than 20 nm. Therefore, satisfying the above (II) can indicate that the content of impurities is small and the content ratio of the single-layer MXene particles is high, and can satisfy the above (1) and (2).

From still another point of view, it is considered as follows. For (1) above, the MAX particles may have a thickness more than 500 nm. Therefore, satisfying the above (III) may indicate that the MAX particles are not contained, and the above (1) may be satisfied. In a conductive film which is formed of a particulate matter and in which MXene particles having a relatively small thickness (for example, 20 nm or less) account for the majority (for example, 98% or more) of the MXene particles, when at least one very thick particle having a thickness of more than 500 nm is present, the orientation of the MXene particles is extremely remarkably lowered. As in the above (III), it can be extremely important that the maximum thickness of the particles contained in the particulate matter is 500 nm or less in order to obtain a conductive film having high orientation of MXene particles.

For the above (II) and (III), the ratio of particles having a thickness of more than 20 nm in the particulate matter and the maximum thickness of the particles contained in the particulate matter are determined in the following manner: a liquid composition (or a slurry to be described later) containing the particulate matter in a liquid medium is dropped onto a flat stage (for example, a silicon wafer having an arithmetic average roughness Ra of 0.5 nm or less), the liquid medium is removed by drying, and using an atomic force microscope (AFM), the thicknesses of all particles within the field of view of the AFM (excluding those in which two or more particles obviously overlap with each other, and those in which the particles extend outside the field of view and the overall shape of the particles cannot be predicted. For example, even in a laminated structure, a structure in which the outlines (edges) of the layers are substantially uniform is regarded as one particle. Also, for example, most (more than half) of the particles are in the field of view, and some of the particles extend out of the field of view, but those that can roughly understand the shape of the particles from the portion in the field of view are included in the measurement target) are measured, and based on the measurement results of at least 40 particles, the maximum thickness can be calculated or determined. The field of view of the AFM may be, for example, 30 µm × 30 µm, but is not limited thereto. The thickness of all particles (here, as described above) within each field of view is measured for a plurality of fields of view until a thickness of at least 40 particles is measured.

As described above, by dropping the particulate matter in the form of a liquid composition (or a slurry to be described later) on a flat stage and drying and removing the liquid medium, the MXene particles contained in the particulate matter can be disposed such that a plane (two-dimensional sheet surface) parallel to the layer of MXene is parallel to the surface of the stage. Therefore, as the measured value of the thickness of the particle, in the case of the MXene particle, the thickness in a direction perpendicular to the layer of MXene (which may correspond to the “thickness” of the MXene particle) can be measured. However, it should be noted that the value of the thickness of the MXene particles measured in this manner may be larger than the actual thickness of the MXene particles because the thickness is measured with a probe by AFM, the liquid medium may remain between the MXene particles and the stage surface, and the like.

From the Lambert-Beer law regarding the absorption of light in a substance, it is understood that the greater the thickness of the particle, the lower the luminance of the light transmitted through the particle. Therefore, from another viewpoint, the particulate matter of the present embodiment can be defined as follows. In the distribution ratio of the luminance of the particles (the total number of particles is defined as a standard (100%)), the luminance (A) at which the ratio of the particles decreases to 1% or less is specified on the higher luminance side than the luminance peak (P), and the luminance width (P - A = W) between the luminance (A) and the peak luminance (P) is obtained. In the present embodiment, the particle exhibiting the peak luminance is considered to be a single-layer MXene particle. It is considered that the particle exhibiting luminance (P ± W) within 1 time the luminance width (W) with respect to the peak luminance (P) is a single-layer/few-layer MXene particle. A particle exhibiting a luminance (smaller than P - W and equal to or larger than P - 3W) smaller than 1 time and equal to or smaller than 3 times the luminance width (W) with respect to the peak luminance (P) is considered to be a multilayer MXene particle (thicker than the few-layer MXene particle). A particle exhibiting a small luminance (less than P -3W) more than 3 times the luminance width (W) with respect to the peak luminance (P) is considered to be a very thick particle (such particles may be, but are not limited to, very thick MXene particles and/or MAX particles.). The particulate matter of the present embodiment may contain the MXene particles 10 described above and satisfy the following (IV), and in some cases, may satisfy at least one of the above (I) to (III).
(IV) In the distribution ratio of the luminance of the particles of the particulate matter (the total number of particles is defined as a standard 100%), the luminance (A) at which the ratio of the particles decreases to 1% or less is specified on the higher luminance side than the luminance peak (P), and the luminance width (P - A = W) between the luminance (A) and the peak luminance (P) is obtained, and a total ratio of particles exhibiting luminance (less than P - 3W) more than 3 times the luminance width (W) and small relative to the peak luminance (P) is less than 0.1%.

Satisfying (IV) above indicates that the ratio of very thick particles in the particulate matter is less than 0.1%. The fact that the particulate matter is substantially free of very thick particles can be extremely important for obtaining a conductive film having high orientation of MXene particles. If an attempt is made to form a conductive film having a thickness of 1 µm by stacking 1000 MXene particles having a thickness of 1 nm, if 1 of the 1000 particles (that is, 0.1%) is a very thick particle, the orientation of the resulting conductive film can be significantly reduced. On the other hand, by satisfying the above (IV), the ratio of very thick particles in the particulate matter is less than 0.1%, and a conductive film having high orientation of MXene particles can be obtained.

In the above (IV), the distribution ratio of the luminance of the particles of the particulate matter is obtained by, using a particle image analyzer, dropping a liquid composition (or slurry to be described later) containing the particulate matter in a liquid medium onto a glass plate, covering the glass plate with a cover glass, irradiating the glass plate with light with a backlight, measuring the luminance of transmitted light while performing image analysis on the transmitted light, and determining the ratio (%) of the number of particles exhibiting luminance in a predetermined range to the total number of particles. The total number of particles to be measured is set to at least 10,000. The predetermined range of the luminance for obtaining the luminance distribution may be appropriately selected, and may be 10, for example.

The slurry of the present embodiment may be a dispersion and/or a suspension containing the above-described particulate matter in a liquid medium. The liquid medium may be an aqueous medium and/or an organic medium, and is preferably an aqueous medium. The aqueous medium is typically water, and in some cases, other liquid substances may be contained in a relatively small amount (for example, 30 mass% or less, preferably 20 mass% or less based on the whole mass of aqueous medium) in addition to water. The organic medium may be, for example, N-methylpyrrolidone, N-methylformamide, N,N-dimethylformamide, ethanol, methanol, dimethylsulfoxide, ethylene glycol, acetic acid, isopropyl alcohol, or the like.

The concentration of the MXene particles 10 (including single-layer MXene particles 10a and multilayer MXene particles 10b) in the slurry of the present embodiment can be appropriately selected according to the slurry application method and the like, but is preferably 10 mg/mL to 30 mg/mL in order to finally obtain a conductive film having high orientation. When the concentration is 10 mg/mL or more, the single-layer MXene particles are easily oriented. When the concentration is 30 mg/mL or less, it is possible to avoid problems such as (i) the viscosity of the slurry becomes high and difficult to handle (it is difficult to apply the slurry to the substrate), (ii) the thickness of the precursor formed in one application of the slurry to the substrate becomes too thick, and (iii) when the thick precursor is dried to remove the liquid medium, the liquid medium in the precursor is rapidly vaporized to disturb the orientation state of the MXene particles or form large voids. As will be described later, in order to obtain a conductive film having high orientation of MXene particles and a predetermined rocking curve half-value width, it is preferable to set the concentration of MXene particles in the slurry to 10 mg/mL to 30 mg/mL to suppress disturbance of the orientation state due to vaporization of the liquid medium. The concentration of the MXene particles 10 is understood as a solid content concentration in the slurry, and the solid content concentration can be measured using, for example, a heating dry weight measurement method, a freeze dry weight measurement method, a filtration weight measurement method, or the like.

In the slurry of the present embodiment, the ratio (single layer MXene purity) of the single-layer MXene particles 10a in the MXene particles 10 is extremely high, and impurities other than the MXene particles 10 are small. In other words, the slurry of the present embodiment can be understood as a highly purified MXene slurry. The slurry of the present embodiment is preferably highly dispersed without aggregation of the MXene particles 10.

The slurry of the present embodiment can be obtained by obtaining a roughly purified MXene slurry, and then subjecting the roughly purified MXene slurry to an operation of centrifugation and recovery/separation/removal of a supernatant in multiple stages. More specifically, it is preferable to perform the operations of centrifugation and recovery of the supernatant in two or more stages, and to perform the operations of centrifugation and removal of the supernatant in the last stage.

The roughly purified MXene slurry can be obtained by selectively etching A atoms from the MAX phase, then roughly removing unnecessary components by centrifugation and removal of the supernatant (collecting/washing the precipitate), and adding a (fresh) liquid medium as necessary. The roughly purified slurry may contain, as MXene particles, desired single-layer MXene particles and multilayer MXene particles that are not formed into a single layer due to insufficient layer separation (delamination), and may further contain impurities other than MXene particles (unreacted MAX particles, the above-described by-products, and the like). Note that the layer separation (delamination) may occur by applying shearing force larger than the intermolecular force acting between the MXene layers to the multilayer MXene. However, if the shearing force is not sufficient, the layer separation cannot be performed (the multilayer cannot be formed into a single layer), and if the shearing force is too large, the MXene is broken (divided into fine MXene). Therefore, it is important to apply the appropriate shearing force. The appropriate shearing force can be applied using a handshake, an automatic shaker, or the like, as described above.

A highly purified MXene slurry of the present embodiment can be obtained by subjecting the roughly purified MXene slurry to centrifugation and collection/separation/removal of the supernatant in multiple stages (adding a (fresh) liquid medium as necessary).

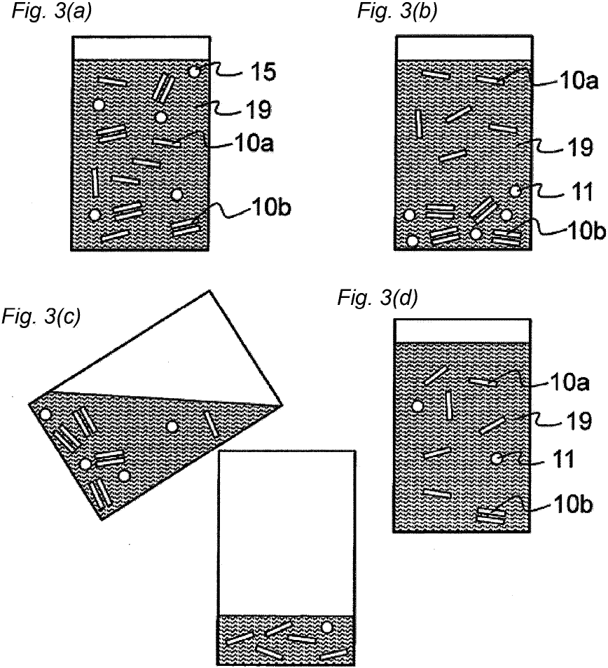

FIGS. 3(a) to 3(d) exemplarily illustrate a case where the operation of centrifugation and recovery of a supernatant is performed on the roughly purified MXene slurry in one stage. Referring to FIG. 3(a), the roughly purified MXene slurry contains, as MXene particles 10, single-layer MXene particles 10a and multilayer MXene particles 10b, and impurities (unreacted MAX particles, the above-described by-products, and the like) 15 in a liquid medium 19. After subjecting to centrifugation, as illustrated in FIG. 3(b), the crude purified slurry is roughly separated into a supernatant rich in single-layer MXene particles and a precipitate rich in multilayer MXene particles and impurities 11. (Among the impurities, the unreacted MAX particles are relatively heavy like the multilayer MXene particles, and thus tend to sink more easily than the single-layer MXene particles. Among the impurities, AlF₃ is relatively heavy (the specific gravity of AlF₃ is 3 g/cm³), and has a shape considered to be granular, and therefore tends to sink more easily than the single-layer MXene particles. In addition, when AlF₃ is present between the layers of the multilayer MXene particles, these are considered to sink together. On the other hand, since the single-layer MXene particles have a two-dimensional shape having a large aspect ratio, the single-layer MXene particles tend to be less likely to sink.) This supernatant is recovered by, for example, decantation illustrated in FIG. 3(c) or the like, and a fresh liquid medium is added as necessary to obtain a slurry after one-stage operation as illustrated in FIG. 3(d). In the slurry after the one-stage operation, multilayer MXene particles 10b and impurities (unreacted MAX particles, the above-described by-products, and the like) 15 are effectively reduced as compared with the roughly purified slurry before the operation (FIG. 3(a)). Such operations of centrifugation and recovery of the supernatant are performed in two or more stages. In the final stage, the supernatant is separated and removed by decantation or the like after centrifugation. Highly purified MXene slurry of the present embodiment can be obtained by adding a fresh liquid medium to the remaining precipitate as necessary. Since a large amount of fine MXene particles can be distributed to the supernatant separated and removed in the final stage, the finally obtained MXene slurry of the present embodiment has effectively reduced fine MXene particles as compared with the MXene slurry before the operation in the final stage. As described above, it is possible to obtain the highly purified MXene slurry of the present embodiment containing the single-layer MXene particles at a high ratio.

Theoretically, since particles to be precipitated are roughly determined by the centrifugal force and time in the centrifugation, it is understood that even when the centrifugation is performed only in one stage or in multiple stages divided into a plurality of stages, if the centrifugal force and the total time are the same, the supernatant portion recovered after the centrifugation is in the same state. However, in practice, when a supernatant (a portion to which a large amount of single-layer MXene particles are distributed) is recovered after centrifugation, precipitates (multilayer MXene particles and impurities) fly up and are mixed in the supernatant. Therefore, it has been found that the supernatant portion recovered after centrifugation is in a different state between a case where the centrifugation is performed in only one stage and a case where the centrifugation is performed in multiple stages divided into a plurality of stages. As described above, the highly purified MXene slurry of the present embodiment can be obtained by performing the operations of centrifugation and recovery/separation/removal of the supernatant in multiple stages. As will be described later, in order to obtain a conductive film having high orientation of MXene particles and a predetermined rocking curve half-value width, it is preferable to perform operations of centrifugation and recovery/separation/removal of the supernatant in multiple stages to obtain a MXene slurry having high purity single-layer MXene. The total number of times of performing the operations of centrifugation and recovery/separation/removal of the supernatant in multiple stages is two or more, preferably three or more.

In the present embodiment, the centrifugal force and time of the centrifugation can be appropriately set. The centrifugal force can be, for example, a relative centrifugal force (RCF) of 3000 × g to 4500 × g, and the single-layer MXene particles can be suppressed from being destroyed by the RCF of 4500 × g or less, and the single-layer MXene particles can be effectively separated from the multilayer MXene particles and impurities by the RCF of 3000 × g or more. The centrifugation time may be, for example, 3 minutes to 60 minutes, and 60 minutes or less can suppress aggregation of the MXene particles and re-multilayering of the single-layer MXene particles, and 3 minutes or more can effectively separate the single-layer MXene particles from the multilayer MXene particles and impurities. Note that, in a case where the centrifugal force of the centrifugation is set to be the same in the multi-stage operation, the time of the centrifugation can be set longer as the stage advances. However, it should be noted that when the centrifugation time is too long, the single-layer MXene particles are compressed for a long time, and the single-layer MXene particles are multilayered again.

The conductive film 30 of the present embodiment can be produced using the MXene slurry of the present embodiment adjusted as described above.

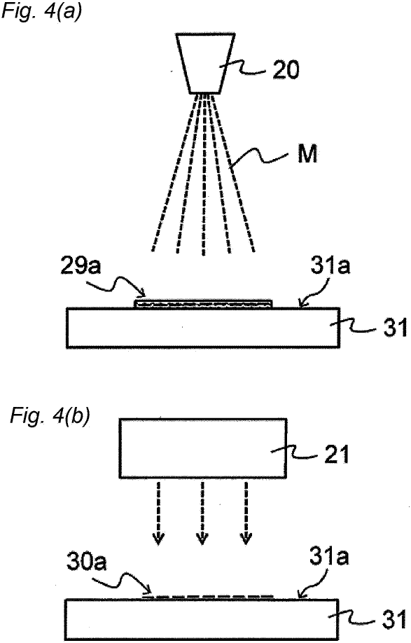

Referring to FIGS. 4(a) and 4(b), the method for producing the conductive film 30 of the present embodiment includes:
FIG. 4(a) applying (supplying or applying) the slurry of the present embodiment onto a substrate 31 to form a precursor of the conductive film 30 containing MXene particles; and
FIG. 4(b) drying the precursor.
Step in FIG. 4(a)

The substrate 31 is not particularly limited as long as it has a flat surface 31a (refer to FIG. 1(a)), and may be made of any suitable material. The substrate may be, for example, a resin film, a metal foil, a printed wiring board, a mounted electronic component, a metal pin, a metal wiring, a metal wire, or the like. When the substrate 31 does not have a flat surface, for example, when the substrate is a filtration membrane, the orientation of the conductive film formed thereon is lowered, and the surface of the conductive film becomes rough, which is not preferable. The surface 31a of the substrate 31 may be equal to or more than the surface smoothness desired for the conductive film 30, and representatively, may have an arithmetic average roughness of 120 nm or less.

As will be described later, in order to obtain a conductive film 30 of the present embodiment having high orientation of MXene particles and a predetermined rocking curve half-value width, it is preferable that the MXene slurry of the present embodiment sufficiently wet-spreads on the substrate surface 31a. When the MXene slurry contains an aqueous medium, the substrate surface 31a may be subjected to a hydrophilic surface treatment in advance to improve wettability.

The method for applying the slurry of the present embodiment on the substrate 31 only needs to be able to obtain the conductive film 30 of the present embodiment having high orientation of MXene particles. More specifically, the application of the slurry may be performed by a spray, spin cast, or blade method, and the MXene particles are well stacked to reduce the distance between the MXene particles, whereby the conductive film 30 having high orientation, high density, and a smooth surface can be obtained. Among them, the spray is preferable because the slurry of the present embodiment (including the MXene particles 10 and the liquid medium) can be thinly applied to the substrate 31 (a thin precursor can be formed), and thus the MXene particles 10 can be supplied in a state of being oriented as parallel as possible (arranged flat) to the substrate surface 31a (at this time, the surface tension of the liquid medium can also preferably act.). The nozzle used for spraying is not particularly limited.

Step in FIG. 4(b)

Thereafter, the precursor on the substrate 31 is dried. In the present invention, the “drying” means removing the liquid medium that can exist in the precursor.

Drying may be performed under mild conditions such as natural drying (typically, it is disposed in an air atmosphere at normal temperature and normal pressure.) or air drying (blowing air), or may be performed under relatively active conditions such as hot air drying (blowing heated air), heat drying, and/or vacuum drying.

The steps in FIG. 4(a) (formation of precursor) and 4(b) (drying) are preferably repeated twice or more in total until a desired conductive film thickness is obtained. In other words, it is preferable to repeat the operation of applying a small amount of slurry onto the substrate 31 in the step in FIG. 4(a) to form a precursor and drying the precursor in the step in FIG. 4(b) a plurality of times. In order to obtain the conductive film 30 having higher orientation, in the step in FIG. 4(a), it is preferable to form a thin precursor by applying a small amount of slurry so that the MXene particles 10 can be supplied in a state of being oriented as parallel as possible to the substrate surface 31a. In addition, in the step in FIG. 4(b), it is preferable to sufficiently dry the precursor every time from a thin precursor to a state in which the liquid medium does not substantially remain so that the supply state (oriented state) of the MXene particles 10 is not disturbed (large voids are not formed) as much as possible when the liquid medium is dried and removed from the precursor.

For example, a combination of spraying and drying may be repeated a plurality of times. More specifically, as illustrated in FIG. 4(a), a small amount of slurry is sprayed as a mist M (In the drawing, indicated by a dotted line) from a nozzle 20 toward the substrate surface 31a to form a precursor layer (first layer) 29a containing MXene particles in a liquid medium. Then, as illustrated in FIG. 4(b), heated air is blown from a warm air dryer 21 in a direction (in the drawing, indicated by a dotted arrow) toward the precursor layer 29a on the substrate surface 31a to be dried, and the liquid medium is removed from the precursor layer 29a, thereby forming the conductive layer (first layer) 30a formed of MXene particles. By repeating such spraying and drying, the conductive film 30 formed by stacking a plurality of conductive layers 30a, 30b, 30c,... (not illustrated) can be formed. The thickness of one conductive layer formed by such spraying and drying is not particularly limited, but may be, for example, 0.01 µm to 1 µm. The number of repetitions of spraying and drying can be appropriately selected according to a desired thickness of the conductive film 30.

Thus, the conductive film 30 of the present embodiment is produced. The conductive film 30 contains the MXene particles 10, and preferably, the liquid medium of the slurry of the present embodiment does not substantially remain. The conductive film 30 does not contain a so-called binder.

As schematically illustrated in FIG. 1(a), the MXene particles 10 exist in a relatively aligned state in the finally obtained conductive film 30, and more specifically, there are many particles 10 in which two-dimensional sheet surfaces of MXene (planes parallel to the layer of MXene) are relatively aligned (preferably parallel) with respect to the substrate surface 31a (in other words, the main surface of the conductive film 30). That is, the conductive film 30 having high orientation of the MXene particles 10 can be obtained. According to the conductive film 30, a surface contact between the MXene particles 10 is achieved, contact between the MXene particles 10 is improved, and high conductivity can be obtained.

The conductive film 30 of the present embodiment has a χ-axis direction rocking curve half-value width of 10.3° or less with respect to a peak of a (001) plane (1 is a natural number multiple of 2) obtained by X-ray diffraction measurement of the conductive film 30.

Although the present invention is not bound by any theory, it can be considered that a conductive film containing MXene particles can be formed by stacking MXene particles (the single-layer MXene particles and the multilayer MXene particles are collectively referred to MXene particles, and the single-layer MXene particles may also be referred to as “nanosheets” or “single flakes”.), and the conductivity of the conductive film is controlled by the orientation of the MXene particles. In order to obtain a conductive film having high conductivity, it is preferable that the MXene particles are oriented as parallel and uniform as possible, in other words, the orientation is high. As a measure indicating the orientation of the MXene particles, the χ-axis direction rocking curve half-value width (hereinafter, also simply referred to as “χ-axis direction rocking curve half-value width”) with respect to the peak of the (001) plane (1 is a natural number multiple of 2) obtained by X-ray diffraction measurement can be applied. The narrower the χ-axis direction rocking curve half-value width is, the higher the orientation of the MXene particles in the conductive film is.

The χ-axis direction rocking curve half-value width is obtained with respect to the peak of the (001) plane (1 is a natural multiple of 2, for example, 1 = 2, 4, 6, 8, 10, 12,...) of MXene contained in the conductive film by measuring X-ray diffraction (XRD) of the conductive film, and is more specifically determined as follows. When the conductive film containing MXene is subjected to XRD measurement, a peak of a (001) plane of MXene is observed in an XRD profile obtained by θ-axis direction scanning. In the XRD profile of the θ-axis direction scan, a plurality of peaks of the (001) plane of MXene can be observed, and any peak may be adopted, but typically, a peak of the (0010) plane (1 = 10) can be adopted. Then, the χ-axis direction rocking curve is obtained by the χ-axis direction scan fixed at 2θ at which the peak of the (001) plane is obtained. The width (°) of the χ-axis angle when one peak is observed in the χ-axis direction rocking curve and the intensity of this peak is halved is defined as a “χ-axis direction rocking curve half-value width”.

For the XRD measurement, for example, a fine X-ray diffraction (µ-XRD) apparatus equipped with a two-dimensional detector can be used, and the two-dimensional X-ray diffraction image obtained thereby can be converted into one dimension (appropriately fitted) to obtain the XRD profile (the vertical axis is intensity and the horizontal axis is 2θ, commonly referred to as the “XRD profile.”) of the θ-axis direction scan and the χ-axis direction locking curve profile (the vertical axis is intensity, and the horizontal axis is χ.) with respect to a predetermined 2θ.

The (001) plane of MXene basically indicates the crystal c-axis direction of MXene, and the peak of the (001) plane can be observed in the XRD profile of the θ-axis direction scan. In the XRD profile of the scan in the θ-axis direction, a peak of the (001) plane can be observed at θ corresponding to the length d of the periodic structure (periodic structure along stacking direction in stacking structure of single-layer MXene and/or multilayer MXene) of MXene according to the Bragg diffraction condition (2d · sinθ = n · λ (n is a natural number, and λ is a wavelength.)), but the length d of the periodic structure can be shifted by the interlayer distance (the distance refers to a distance between any two adjacent MXene layers in the conductive film regardless of the single-layer MXene and the multilayer MXene.) of MXene, the thickness of the MXene layer, and the like. When the above formula: MₘXₙ is MXene represented by Ti₃C₂, the peak of the (0010) plane is observed as a peak near 2θ = 35 to 40° (approximately 36°). When the χ-axis direction locking curve is acquired with respect to the peak of the (001) plane, the intensity is maximized (a peak is observed) at an angle perpendicular to (or near) the principal surface of the conductive film. As the crystal c-axis direction of MXene is aligned, the strength is significantly reduced when the MXene is deviated from the perpendicular angle. Therefore, the smaller the half-value width of the peak in the χ axis direction rocking curve, the more aligned the crystal c axis direction of MXene, in other words, the higher the orientation (refer to FIG. 1(a)).

The conductive film of the present embodiment has a χ-axis direction rocking curve half-value width of 10.3° or less, and has high orientation of MXene particles, so that high conductivity, for example, conductivity of 10,000 S/cm or more can be obtained. The χ-axis direction rocking curve half-value width is preferably 8.8° or less, so that higher conductivity can be achieved. The lower limit of the χ-axis direction rocking curve half-value width is not particularly present, but may be, for example, 3° or more.

Specifically, the conductive film of the present embodiment can have a conductivity of 12,000 S/cm or more. The conductivity of the conductive film may be preferably 14,000 S/cm or more, and there is no particular upper limit, but may be, for example, 30,000 S/cm or less. The conductivity can be calculated from the measured values obtained by measuring the resistivity and the thickness of the conductive film.

Furthermore, in the conductive film of the present embodiment, since the χ-axis direction rocking curve half-value width is 10.3° or less and the orientation of the MXene particles is high, a high density can be obtained, and specifically, a density of 3.00 g/cm³ or more can be realized. The high orientation and density indicate that the ratio of the single-layer MXene particles in the conductive film is high. The density of the conductive film may be preferably 3.40 g/cm³ or more, and the upper limit is not particularly present, but may be, for example, 4.5 g/cm³ or less. The density can be calculated from the measurement values obtained by measuring the mass and thickness of the conductive film for a portion having a predetermined area in the conductive film.

Furthermore, in the conductive film of the present embodiment, since the χ-axis direction rocking curve half-value width is 10.3° or less and the orientation of the MXene particles is high, a high surface smoothness can be obtained, and specifically, an arithmetic average roughness (Ra) of 120 nm or less can be realized. The high orientation and surface smoothness indicate that the conductive film is uniform and flat. Ra may be preferably 100 nm or less, more preferably 80 nm or less, and there is no particular lower limit, but may be, for example, 1 nm or more. Ra can be measured for the exposed surface of the conductive film using a surface roughness measurement machine.

The conductive film of the present embodiment may be in the form of a so-called film, and specifically, it may have two main surfaces facing each other. As to the conductive film, its thickness, its shape and dimensions when viewed in a plan view, and the like can be appropriately selected depending on the use of the conductive film.

The conductive film of the present embodiment can be used for any suitable application. It is suitably used as an electromagnetic shield (EMI shield) for which high conductivity is required.

By using the conductive film of the present embodiment, an electromagnetic shield having a high shielding rate (EMI shielding property) can be obtained. In general, the EMI shielding property is calculated with respect to the conductivity as shown in Table 1 on the basis of the following Equation (1):

$$\text{SE = 50 + 10log} \left(\frac{\text{σ}}{\text{f}}\right) + 1.7 \text{t} \sqrt{\text{σ} \text{f}}$$

In Equation (1), SE is EMI shielding property (dB), σ is conductivity (S/cm), f is a frequency (MHz) of an electromagnetic wave, and t is a thickness (cm) of a film.

TABLE 1

| Conductivity (S/cm) | EMI shield property (dB)* |
|---|---|
| 100 | 41 |
| 1,000 | 52 |
| 5,000 | 61 |
| 10,000 | 65 |
| 12,000 | 67 |
| 14,000 | 68 |

*Here, f = 1,000 MHz and t = 0.001 cm.

As understood from Table 1, when the conductivity is 10,000 S/cm or more, high EMI shielding properties are obtained. According to the conductive film of the present embodiment, since the conductivity is 10,000 S/cm or more, preferably 12,000 S/cm or more, in a case where the thickness is constant, higher EMI shielding properties can be obtained, or a sufficient EMI shielding effect can be obtained even if the thickness is reduced.

Although the conductive film, the slurry, and the method for producing a conductive film using the slurry according to one embodiment of the present invention have been described in detail above, the present invention can be variously modified. It should be noted that the conductive film according to the present invention may be produced by a method different from the producing method in the above-described embodiment, and the method for producing a conductive film of the present invention is not limited only to one that provides the conductive film according to the above-described embodiment.

### EXAMPLES

### Comparative Example 1 and Examples 1 and 2: MXene Slurry

### Preparation of MXene Slurry

MXene slurries of Comparative Example 1 and Examples 1 and 2 were prepared by the following procedure.

TiC powder, Ti powder, and Al powder (all manufactured by Kojundo Chemical Laboratory Co., Ltd.) were placed in a ball mill containing zirconia balls at a molar ratio of 2 : 1 : 1 and mixed for 24 hours. The obtained mixed powder was fired at 1350° C. for 2 hours under an Ar atmosphere. The fired body (block) thus obtained was crushed with an end mill to a maximum size of 40 µm or less. In this way, Ti₃AlC₂ particles (powder) were obtained as MAX particles.

The Ti₃AlC₂ particles (powder) obtained above were added to 9 mol/L hydrochloric acid together with LiF (for 1 g of Ti₃AlC₂ particles, 1 g of LiF and 10 mL of 9 mol/L hydrochloric acid were used.), and stirred with a stirrer at 35° C. for 24 hours to obtain a solid-liquid mixture (suspension) containing a solid component derived from the Ti₃AlC₂ particles. On the other hand, an operation of separating and removing a supernatant liquid by washing with pure water and decantation using a centrifuge (remaining precipitate excluding the supernatant is washed again) was repeated about 10 times. Then, a mixture obtained by adding pure water to the precipitate was stirred for 15 minutes with an automatic shaker. With this, a roughly purified MXene slurry was obtained.

The roughly purified MXene slurry obtained above was placed in a centrifuge tube having a volume of 50 mL, and centrifuged at 3,500 × g of RCF for 3 minutes using a centrifuge (Sorvall Legend XT, manufactured by Thermo Fisher Scientific, the same applies to the following.). The supernatant thus centrifuged was recovered by decantation to obtain a MXene slurry after one-stage operation. The remaining precipitate, excluding the supernatant, was not subsequently used.

The MXene slurry after the one-stage operation was placed in a centrifuge tube having a volume of 50 mL, and centrifuged for 15 minutes with an RCF of 3,500 × g using a centrifuge. The supernatant thus centrifuged was recovered by decantation to obtain a MXene slurry after two-stage operation. The remaining precipitate (high-concentration slurry) excluding the supernatant was diluted by addition of pure water to obtain a MXene slurry (solid content concentration: 15 mg/mL) of Comparative Example 1.

The MXene slurry after the two-stage operation was placed in a centrifuge tube having a volume of 50 mL, and centrifuged for 30 minutes with an RCF of 3,500 × g using a centrifuge. The supernatant thus centrifuged was recovered by decantation to obtain a MXene slurry after three-stage operation. The remaining precipitate (high-concentration slurry) excluding the supernatant was diluted by addition of pure water to obtain a MXene slurry of Example 1 (solid content concentration: 15 mg/mL).

The MXene slurry after the three-stage operation was placed in a centrifuge tube having a volume of 50 mL, and centrifuged for 45 minutes with an RCF of 3,500 × g using a centrifuge. The supernatant thus centrifuged was separated and removed by decantation. The separated and removed supernatant was not used thereafter. The remaining precipitate (high-concentration slurry) excluding the supernatant was diluted by addition of pure water to obtain a MXene slurry of Example 2 (solid content concentration: 15 mg/mL).

### Evaluation of MXene Slurry

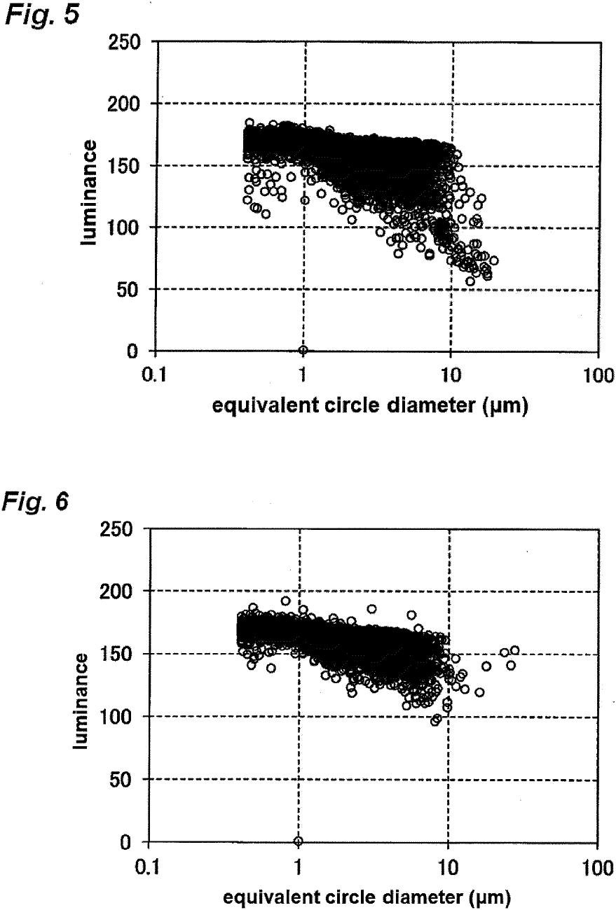

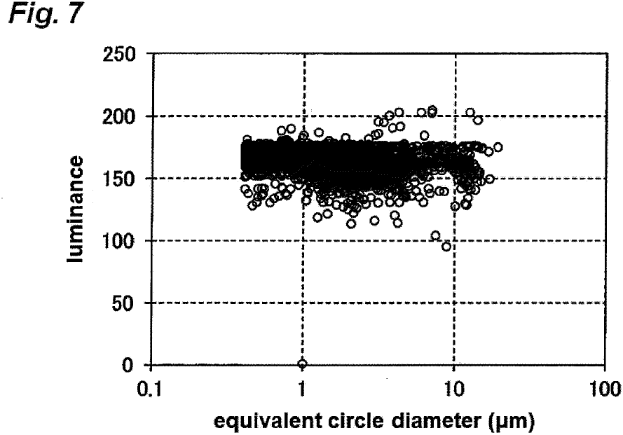

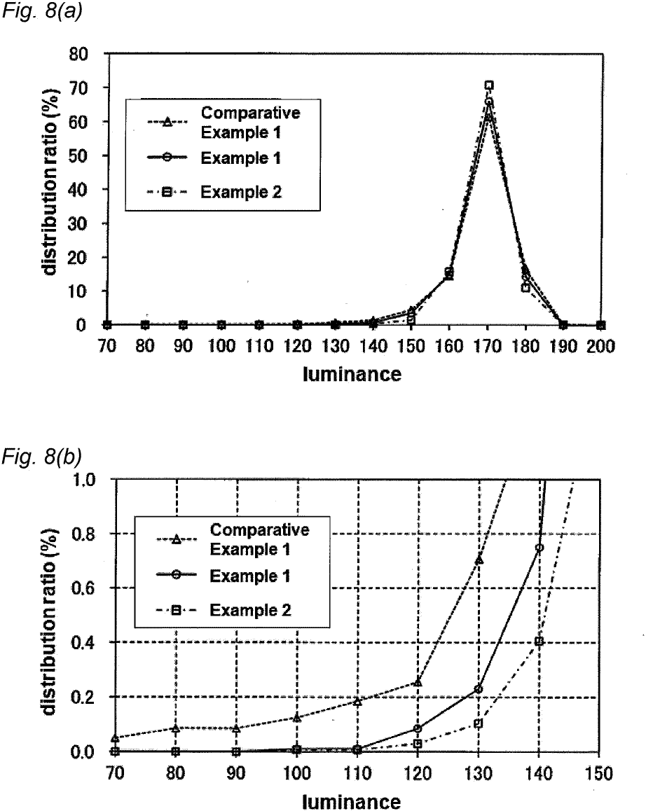

For each of the MXene slurries of Comparative Example 1 and Examples 1 and 2 prepared as described above, a sample of the MXene slurry was dropped onto a glass plate, covered with a cover glass, irradiated with light from a backlight, and the transmitted light was image-analyzed to examine the equivalent circle diameter (µm) representing the size of the particle (which is considered to be the size of the two-dimensional sheet surface in the case of the MXene particle) and the distribution of the luminance of the particle, using a particle image analyzer (“MORPHOLOGI 4”, manufactured by Malvern Panalytical). The results are illustrated in FIGS. 5 to 7 (Note that since the particles can move during the photographing of the particle image, it is considered that the equivalent circle diameter is slightly overestimated.). Further, from these results, the distribution ratio (ratio of the number of particles having luminance in a predetermined range based on the total number of particles (100%)) of the luminance of the particles was examined. The predetermined range was set to 10, with a luminance of 60 or less, more than 60 and 70 or less, more than 70 and 80 or less,..., more than 180 and 190 or less, more than 190 and 200 or less, and more than 200, and for example, particles having a luminance of more than 120 and 130 or less were labeled as particles of luminance “130”. The results are illustrated in FIGS. 8(a) and 8(b). Particles with higher luminance are considered to be thin particles, that is, single-layer MXene particles, and particles with lower luminance are considered to be thicker particles, that is, multilayer MXene particles and impurities (the unreacted MAX particles and by-products, and by-products may be present between the layers of the multilayer MXene particles.). As can be understood from the illustrated results, in the MXene slurry of Example 1 (FIG. 6), particles having a luminance of 100 or less (that is, the thickness is considerably large.) are hardly observed as compared with the MXene slurry of Comparative Example 1 (FIG. 5), and it is understood that the single-layer MXene particles can be highly purified. Furthermore, in the MXene slurry of Example 2 (FIG. 7), (that is, the thickness is large.) particles having a luminance of 120 or less are hardly observed, and it is understood that the single-layer MXene particles can be further purified. Note that the results illustrated in FIG. 5 to 8(b) can be compared because they are measured under the same conditions, but the absolute value of the luminance may depend on the intensity of the backlight.

Referring to FIG. 8(a), the peak (P) of the luminance was 170, and the luminance (A) at which the ratio of particles decreased to 1% or less on the higher luminance side was 190. Therefore, the luminance width (P - A = W) between the luminance (A) and the peak luminance (P) was 20. It was considered that the particle exhibiting luminance (P ± W = 150 to 190) within one time the luminance width (W = 20) with respect to the peak luminance (P = 170) is a single-layer/few-layer MXene particle. A particle exhibiting a luminance (smaller than P - W and equal to or larger than P - 3W = 110 to less than 150) smaller than 1 time and equal to or smaller than 3 times the luminance width (W = 20) with respect to the peak luminance (P = 170) is considered to be a multilayer MXene particle (thicker than the few-layer MXene particle). For the peak luminance (P = 170), a particle exhibiting a small luminance (less than P - 3 W = less than 110) more than 3 times the luminance width (W = 20) was considered to be a very thick particle. In the luminance distribution illustrated in FIGS. 8(a) and 8(b), since the predetermined range of the luminance is set to 10, the luminance (less than P - 3 W = less than 110) that is more than 3 times as small as the luminance width (W = 20) with respect to the peak luminance (P = 170) is 100 or less. Referring to FIG. 8(b), in the MXene slurry of Comparative Example 1, the ratio of particles having a luminance of 100 was 0.1% or more, specifically 0.13%, and the total ratio of particles having a luminance of 100 or less was 0.1% or more, specifically 0.35%. In contrast, in the MXene slurries of Example 1 and Example 2, the ratio of particles having a luminance of 100 was less than 0.1%, specifically 0.01%, and the total ratio of particles having a luminance of 100 or less was less than 0.1%, specifically 0.01%.

In addition, for each of the MXene slurries of Comparative Example 1 and Examples 1 and 2 prepared as described above, a sample (solid concentration was as described above) was dropped onto a silicon wafer (arithmetic average roughness Ra was less than 0.5 nm), dried, and the thickness of particles contained in the sample was measured by AFM. The size of the field of view was set to 30 µm × 30 µm, the height of all particles (here, as described above) in one field of view was measured, and different fields of view were set until measurement results of at least 40 particles were obtained. The results are shown in Table 2 and Table 3. For example, in Example 1, the thicknesses of 8 particles present in the field of view 1 were measured, then the thicknesses of 8 particles present in the field of view 2 were measured,... (fields of view 3 to 5), and then the thicknesses of 6 particles present in the field of view 6 were measured to obtain the measurement results of the thicknesses of 42 particles in total.

TABLE 2

| | Field of view | Thickness (nm) | | | | | | | | | | | |
|---|---|---|---|---|---|---|---|---|---|---|---|---|---|
| Comparative Example 1 | 1 | 3.774 | 3.184 | 3.5 | 3.441 | 7.611 | 3.224 | 2.969 | 3.378 | 3.484 | | | |
| | 2 | 3.667 | 3.619 | 3.592 | | | | | | | | | |
| | 3 | 3.423 | 3.833 | 3.665 | 3.747 | 3.836 | 4.61 | 3.846 | 3.92 | | | | |
| | 4 | 3.622 | 3.825 | 4.022 | 3.648 | 3.519 | 4.046 | | | | | | |
| | 5 | 3.897 | 3.555 | 3.507 | 3.764 | 4.019 | | | | | | | |
| | 6 | 23.638 | 4.925 | 4.863 | 3.742 | 3.575 | 3.943 | | | | | | |
| | 7 | 3.048 | 6.643 | 3.647 | | | | | | | | | |
| | 8 | 3.53 | 3.656 | 3.616 | 3.719 | 3.635 | 3.843 | | | | | | |
| | 9 | 37.39 | | | | | | | | | | | |
| | 10 | > 500 | | | | | | | | | | | |
| Example 1 | 1 | 3.572 | 3.471 | 3.648 | 3.813 | 3.606 | 3.58 | 3.676 | 3.772 | | | | |
| | 2 | 3.75 | 7.929 | 9.534 | 13.386 | 3.732 | 3.704 | 6.201 | 3.736 | | | | |
| | 3 | 3.663 | 3.741 | 3.664 | 4.027 | 5.419 | 4.067 | 4.075 | | | | | |
| | 4 | 3.732 | 3.899 | 4.149 | 4.255 | 3.702 | 4.051 | 3.957 | | | | | |
| | 5 | 3.701 | 3.635 | 3.671 | 4.17 | 3.98 | 3.922 | | | | | | |
| | 6 | 3.968 | 4.014 | 4.008 | 3.962 | 5.562 | 3.749 | | | | | | |
| Example 2 | 1 | 3.643 | 3.537 | 3.64 | 3.75 | 3.58 | 3.631 | 3.614 | 4.013 | 3.882 | 3.638 | 3.602 | 3.564 |
| | 2 | 3.605 | 3.721 | 3.682 | 3.649 | 4.067 | 3.722 | 3.652 | 3.625 | 5.064 | 3.679 | | |
| | 3 | 3.49 | 3.594 | 14.139 | 3.602 | 3.82 | 3.868 | 3.948 | 3.986 | | | | |
| | 4 | 3.778 | 3.705 | 3.654 | 6.381 | 3.685 | 4.251 | 3.652 | 3.787 | | | | |
| | 5 | 5.617 | 3.875 | 3.828 | 3.725 | 3.843 | 3.509 | | | | | | |
| | 6 | 5.618 | 3.723 | 3.656 | 3.629 | 3.553 | 3.594 | 3.638 | | | | | |

TABLE 3

Distribution of thicknesses of particles (number)

| | 3 nm or less | More than 3 nm and 4 nm or less | More than 4 nm and 5 nm or less | More than 5 nm and 6 nm or less | More than 6 nm and 10 nm or less | More than 10 nm |
|---|---|---|---|---|---|---|
| Comparative Example 1 | 1 | 36 | 6 | 0 | 2 | 3 |
| Example 1 | 0 | 27 | 9 | 2 | 3 | 1 |
| Example 2 | 0 | 43 | 3 | 3 | 1 | 1 |

Referring to Tables 2 and 3, in the MXene slurry of Comparative Example 1, there were 3 particles having a thickness of more than 20 nm among a total of 48 particles, and thus the ratio of the particles having a thickness of more than 20 nm in the particulate matter was 6%. In the MXene slurry of Comparative Example 1, the maximum thickness of the particles contained in the particulate matter is more than 500 nm, and the particles having a thickness of more than 500 nm are considered to be MAX particles. On the other hand, in the MXene slurry of Example 1, there were 0 particles having a thickness of more than 20 nm among the total of 42 particles, and thus the ratio of the particles having a thickness of more than 20 nm in the particulate matter was 0%. In the MXene slurry of Example 1, the maximum thickness of the particles contained in the particulate matter was about 13 nm, only one particle having a thickness of more than 10 nm was present, and the other particles were all 10 nm or less in thickness. In the MXene slurry of Example 2, there were 0 particles having a thickness of more than 20 nm among the total of 51 particles, and thus the ratio of the particles having a thickness of more than 20 nm in the particulate matter was 0%. In the MXene slurry of Example 2, the maximum thickness of the particles contained in the particulate matter was about 14 nm, only one particle having a thickness of more than 10 nm was present, and the other particles were all 10 nm or less in thickness. The particles having a thickness of 15 nm or less are considered to be single-layer/few-layer MXene particles, and the particles having a thickness of 4 nm or less are considered to be single-layer MXene particles.

It was confirmed that the particle thickness distribution by AFM measurement shown in Table 3 substantially corresponded to the distribution ratio of luminance by the particle image analyzer (“MORPHOLOGI 4”) measurement illustrated in FIGS. 8(a) and 8(b). In FIG. 8(a), the particles exhibiting luminance of 150 to 190 are considered to be single-layer/few-layer MXene particles, which may correspond to particles having a thickness of 10 nm or less in AFM measurement. The particles exhibiting a luminance of 110 to less than 150 in FIG. 8(b) are considered to be multilayer MXene particles (thicker than the few-layer MXene particles), which may be considered to correspond to particles having a thickness of more than 10 nm and 30 nm or less in AFM measurement. Particles exhibiting luminance below 110 (100 or less) in FIGS. 8(a) and 8(b) are considered very thick particles, which may correspond to particles above 30 nm in AFM measurements.

In addition, for each of the MXene slurries of Comparative Example 1 and Examples 1 and 2 prepared as described above, the sample (the solid content concentration was as described above) was dried, the contents of the Ti element and the Al element were measured by ICP-AES, and the ratio (mol%) of Al to Ti was calculated from these measured values. The results are shown in Table 4. It is considered that the multilayer MXene particles and impurities (unreacted MAX particles and by-products) are reduced as the ratio of Al to Ti is lower, and thus the ratio of the single-layer MXene particles in the MXene particles is higher.

TABLE 4

| | Comparative Example 1 | Example 1 | Example 2 |
|---|---|---|---|
| Al/Ti (mol%) | 1.79 | 0.27 | 0.15 |

As understood from Table 4, it is understood that the ratio (mol%) of Al to Ti is reduced (more specifically, the ratio of Al to Ti in the slurry is 0.30 mol% or less.) in the MXene slurry of Example 1 as compared with the MXene slurry of Comparative Example 1, and the single-layer MXene particles can be highly purified. Furthermore, it is understood that in the MXene slurry of Example 2, the ratio (mol%) of Al to Ti is further reduced, and the single-layer MXene particles can be further purified.

### Comparative Example 2 and Examples 3 and 4: Conductive Film

### Preparation of Conductive Film

Conductive films (MXene films) of Comparative Example 2 and Examples 3 and 4 were prepared by the following procedure. Except that the MXene slurry of Comparative Example 1 was used as the conductive film of Comparative Example 2, and the MXene slurries of Examples 1 and 2 were used as the conductive films of Examples 3 and 4, the same procedure as described below was carried out to prepare the conductive films of Comparative Example 2 and Examples 3 and 4.

Each MXene slurry prepared above was diluted by addition of pure water to prepare a slurry having a solid content concentration of about 15 mg/mL.

A 50 µm-thick polyethylene terephthalate film subjected to hydrophilization surface treatment (ultraviolet-ozone treatment) was prepared as a substrate. On the surface of the substrate, a square region of 3 cm × 3 cm was left exposed, and the periphery thereof was masked with a scotch tape.

The slurry prepared above (solid content concentration: 15 mg/mL) was sprayed onto the substrate with an air brush (spray work HG air brush wide (trigger type), air brush system No. 53, spray work power compressor 74553, manufactured by Tamia Corporation) at an air pressure of 0.40 MPa (absolute pressure). After spraying, hot air was blown with a hand dryer (EH 5206 P-A manufactured by Panasonic Corporation) to dry the film. The thickness per layer of the precursor by spraying was several tens of nm. The precursor layer was sprayed and then sufficiently dried by blowing warm air (the substrate temperature during drying was considered to be 40° C. or higher, effectively promoting drying.). The operations of spraying and drying were repeated 100 times or more in total. Thereafter, drying was performed at 80° C. for 16 hours in a vacuum oven. Thus, a conductive film having a thickness of 3 to 5 µm was prepared on a square region of 3 cm × 3 cm of the substrate. On the scotch tape applied to the substrate, the sprayed mist was repelled, so that a conductive film was not formed.

### Evaluation of Conductive Film

Each of the conductive films of Comparative Example 2 and Examples 3 and 4 produced as described above was evaluated for the following items.

### χ-Axis Direction Rocking Curve Half-Value Width

The conductive film with a substrate (sample) prepared above was punched out or cut out together with the substrate, XRD measurement was performed using µ-XRD (AXS D8 DISCOVER with GADDS manufactured by Bruker Corporation), and the χ-axis direction rocking curve half-value width was calculated. More specifically, a two-dimensional X-ray diffraction image of the conductive film was obtained by XRD measurement (characteristic X-ray: CuKα = 1.54 Å), a peak at 2θ = 35 to 40° (around 36°) in the XRD profile of θ-axis direction scan (a peak of a (0010) plane of MXene in which MₘXₙ is represented by Ti₃C₂) was examined, a χ-axis direction rocking curve was obtained for this peak, and a χ-axis direction rocking curve half-value width was calculated. The χ-axis direction rocking curve half-value width was an average value of the measured values at two points obtained by XRD measurement. The results are shown in Table 5 (in Table 5, the χ-axis direction rocking curve half-value width is simply referred to as “half width”.).

### Conductivity

In addition, the conductivity (S/cm) of the conductive film with a substrate was measured using a portion other than the portion punched out as described above (the same applies hereinafter) in the conductive film with a substrate (sample) prepared as described above. More specifically, for the conductivity, the resistivity (surface resistivity) (Q) and the thickness (µm) (obtained by subtracting the thickness of the substrate) were measured three times at a total of five locations of four corners and the center per sample, the conductivity (S/cm) was calculated from the average value of the measurements performed three times, and the average value of the conductivities at the five locations thus obtained was adopted. For resistivity measurement, a low resistivity meter (Loresta AX MCP-T 370, manufactured by Mitsubishi Chemical Analytech) was used. A micrometer (MDH-25 MB, manufactured by Mitutoyo Corporation) was used for the thickness measurement. The results are also shown in Table 5.

### Density

In the conductive film with a substrate (sample) prepared above, the same total of five points as in the thickness measurement described above were cut out in a region of 1 cm × 1 cm, the mass of the cut portion before and after peeling off the conductive film was measured, and the mass of the conductive film per unit area (1 cm²) was calculated as a difference between the measured values. Then, the density of the conductive film was calculated by dividing the mass of the conductive film per unit area (1 cm²) by the thickness obtained by the thickness measurement.

### Ra (Arithmetic Average Roughness)

For the exposed surface of the conductive film with substrate (sample) prepared as described above, Ra (arithmetic average roughness) was measured at three points using a surface roughness measuring instrument (NewView 7300 manufactured by ZYGO) by a white light interferometer system, and the average value of Ra at the three points thus obtained was adopted.

TABLE 5

| | Comparative Example 2 | Example 3 | Example 4 |
|---|---|---|---|
| MXene slurry | Comparative Example 1 | Example 1 | Example 2 |
| Half-value width (°) | 13.2 | 10.3 | 8.8 |
| Conductivity (S/cm) | 8300 | 12900 | 14600 |
| Density (g/cm³) | 2.54 | 3.37 | 3.50 |
| Ra (nm) | 314 | 118 | 74 |

### Observation of Appearance of Conductive Film

A label having colors and letters on the label surface was put on the conductive film with a substrate (sample) prepared above such that the label surface was obliquely opposed to the exposed surface of the conductive film (internal angle: about 45°), and the reflection of the label surface on the exposed surface of the conductive film was observed. On the label surface, (i) a black region, (ii) a region in which black characters are described on a white background, (iii) a region in which white characters and black characters are described on a green background, and (iv) a region in which green characters and black characters are described on a white background were arranged in parallel with each other. The higher the degree of reflection on the conductive film, the higher the light reflectivity and the higher the orientation. In the conductive film of Comparative Example 2, reflection on the label surface was hardly observed, and (i) a blackish region, (ii) a whitish region, (iii) a greenish region, and (iv) a whitish region could be discriminated. In the conductive film of Example 3, glare of the label surface was observed, and (i) a black region, (ii) a black character like in a white region, (iii) a white and black character like in a green region, and (iv) a green and black character like in a white region could be discriminated. In the conductive film of Example 4, glare on the label surface was clearly recognized, and (i) a black region, (ii) a region in which black characters were described in white characters, (iii) a region in which white characters and black characters were described in green background, and (iv) a region in which green characters and black characters were described in white characters could be clearly distinguished.

### Observation of Cross-Sectional SEM of Conductive Film

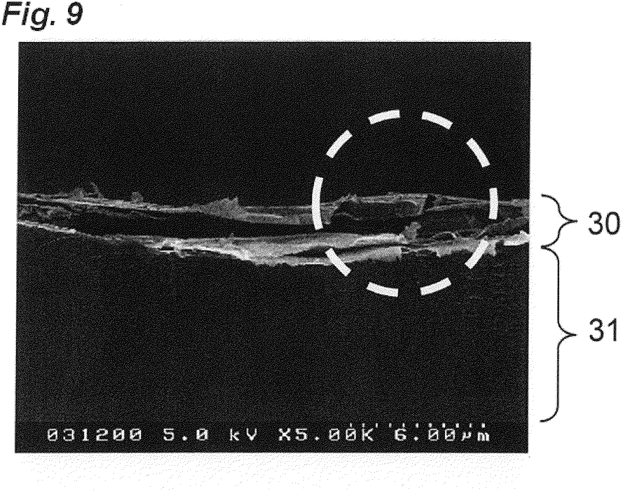

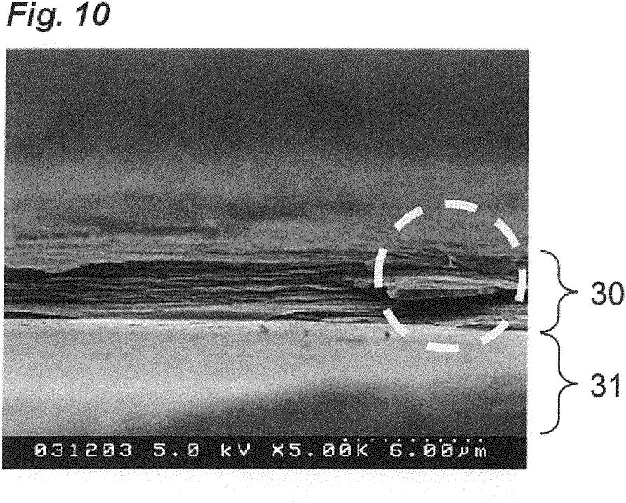

The conductive film with a substrate (sample) prepared above was cut in a thickness direction, and a cross section thereof was observed with a scanning electron microscope (SEM) (manufactured by Hitachi, Ltd., S-5000). A cross-sectional SEM photograph of the sample is illustrated in FIGS. 9 to 11. FIGS. 9 to 11 illustrate a state in which the conductive film 30 is formed on the substrate 31. As understood from the illustrated results, in the conductive film of Comparative Example 2 (FIG. 9), presence of particulate crystalline impurities (refer to the region surrounded by the dotted line in the drawing) was confirmed, and multilayer MXene particles (not illustrated) were present in the conductive film, so that the layer structure of MXene was considerably disturbed. The particulate crystalline impurities that can be observed in the SEM photograph are considered to be unreacted MAX particles (or multilayer MXene particles that have not been delaminated) (it is considered that there is a high possibility that AlF₃ is present between layers of the multilayer MXene particles, but it is considered that AlF₃ does not have a size that can be easily detected by SEM.). In the conductive film of Example 3 (FIG. 10), it was confirmed that particulate crystalline impurities were present (refer to the region surrounded by the dotted line in the drawing), and the stacking of the single-layer MXene particles was inhibited, but the single-layer MXene particles were stacked with substantially favorable orientation. Furthermore, in the conductive film of Example 4 (FIG. 11), no disturbance of the layer structure of MXene was observed, and the single-layer MXene particles were stacked with extremely high orientation.

The conductive film of the present invention can be used in any suitable application, and can be particularly, preferably used, for example, as electromagnetic shield.

Reference Numerals

| | |
|---|---|
| 1a,1b | layer body (MₘXₙ layer) |
| 3a, 5a, 3b, 5b | modifier or terminal T |
| 7a, 7b | MXene layer |
| 10, 10a, 10b | MXene (layered material) particles |
| 19 | impurities |
| 20 | nozzle |
| 21 | hot air dryer |
| 29 a | precursor layer (first layer) |
| 30 | conductive film |
| 30 a | conductive layer (first layer) |
| 31 | substrate |
| 31 a | sub strate surface |

1. A conductive film comprising:
particles of a layered material including one or plural layers, wherein the one or plural layers include a layer body represented by: 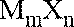
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein the modifier or terminal T is at least one selected from the group consisting of a hydroxyl group, a fluorine atom, a chlorine atom, an oxygen atom, or a hydrogen atom,
wherein a χ-axis direction rocking curve half-value width for a peak of a (001) plane obtained by X-ray diffraction measurement of the conductive film is 10.3° or less,
wherein 1 is a natural number multiple of 2, and
wherein the conductive film has a conductivity of 10,000 S/cm or more.

2. The conductive film according to claim 1, wherein the χ-axis direction rocking curve half-value width is 8.8° or less.

3. The conductive film according to claim 1, wherein the conductivity is 12,000 S/cm or more.

4. The conductive film according to claim 1, wherein the conductive film has a density of 3.00 g/cm³ or more.

5. The conductive film according to claim 1, wherein the conductive film has an arithmetic average roughness of 120 nm or less.

6. The conductive film according to claim 1, wherein the conductive film is constructed as an electromagnetic shield.

7. A conductive film comprising:
particles of a layered material including one or plural layers, wherein the one or plural layers include a layer body represented by: 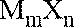
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein the modifier or terminal T is at least one selected from the group consisting of a hydroxyl group, a fluorine atom, a chlorine atom, an oxygen atom, or a hydrogen atom; and
particles containing A,
wherein a ratio of the A to the M is 0.30 mol% or less,
wherein the A is at least one element of Group 12, 13, 14, 15, or 16, and
wherein the conductive film has a conductivity of 10,000 S/cm or more.

8. The conductive film according to claim 7, wherein the M is Ti and the A is Al.

9. A conductive film comprising:
particles of a layered material including one or plural layers, wherein the one or plural layers include a layer body represented by: 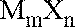
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein the modifier or terminal T is at least one selected from the group consisting of a hydroxyl group, a fluorine atom, a chlorine atom, an oxygen atom, or a hydrogen atom,
wherein a ratio of particles more than 20 nm in thickness in the conductive film is less than 2%, and
wherein the conductive film has a conductivity of 10,000 S/cm or more.

10. The conductive film according to claim 9, further comprising:
particles containing A,
wherein a ratio of the A to the M is 0.30 mol% or less, and
wherein the A is at least one element of Group 12, 13, 14, 15, or 16.

11. A conductive film comprising:
particles of a layered material including one or plural layers, wherein the one or plural layers include a layer body represented by: 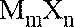
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein the modifier or terminal T is at least one selected from the group consisting of a hydroxyl group, a fluorine atom, a chlorine atom, an oxygen atom, or a hydrogen atom,
wherein a maximum thickness of the particles contained in the conductive film is 500 nm or less, and
wherein the conductive film has a conductivity of 10,000 S/cm or more.

12. The conductive film according to claim 11, wherein a ratio of particles more than 20 nm in thickness in the particulate matter as the raw material of the conductive film is less than 2%.

13. A slurry comprising:
a liquid medium;
particles of a layered material including one or plural layers in the liquid medium, wherein the one or plural layers include a layer body represented by: 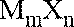
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein the modifier or terminal T is at least one selected from the group consisting of a hydroxyl group, a fluorine atom, a chlorine atom, an oxygen atom, or a hydrogen atom; and
particles containing A in the liquid medium,
wherein a ratio of the A to the M is 0.30 mol% or less, and
wherein the A is at least one element of Group 12, 13, 14, 15, or 16.

14. A method for producing a conductive film, the method comprising:
(a) applying the slurry of claim 13 onto a substrate to form a precursor including the particles of the layered material; and
(b) drying the precursor to form the conductive film.

15. The method for producing a conductive film according to claim 14, wherein the applying of the slurry is performed by spraying, spin casting, or a blade method.

16. The method for producing a conductive film according to claim 14, wherein the (a) and the (b) are repeated twice or more in total.

17. The method for producing a conductive film according to claim 14, wherein the formed conductive film has:
a χ-axis direction rocking curve half-value width for a peak of a (001) plane obtained by X-ray diffraction measurement of the conductive film is 10.3° or less, wherein 1 is a natural number multiple of 2, and
a conductivity of 10,000 S/cm or more.
